(19) United States
(12) Patent Application Publication
(10) Pub. No.: US 2019/0051758 A1
(43) Pub. Date: Feb. 14, 2019

(54) THIN FILM TRANSISTOR COMPRISING OXIDE SEMICONDUCTOR LAYER

(71) Applicant: Kabushiki Kaisha Kobe Seiko Sho (Kobe Steel, Ltd.), Kobe-shi (JP)

(72) Inventors: Mototaka OCHI, Hyogo (JP); Kohei NISHIYAMA, Hyogo (JP); Hiroshi GOTO, Hyogo (JP); Toshihiro KUGIMIYA, Hyogo (JP)

(73) Assignee: Kabushiki Kaisha Kobe Seiko Sho (Kobe Steel, Ltd.), Kobe-shi (JP)

(21) Appl. No.: 16/079,915

(22) PCT Filed: Feb. 2, 2017
(86) PCT No.: PCT/JP2017/003851

§ 371 Date: Aug. 24, 2018

(30) Foreign Application Priority Data
Feb. 26, 2016 (JP) 2016-035806
Sep. 16, 2016 (JP) 2016-182146

(51) Int. Cl. H01L 29/786; H01L 29/66; H01L 23/31; H01L 29/51

(52) U.S. Cl. CPC H01L 29/78693; H01L 29/51; H01L 23/3171; H01L 29/66742

(57) ABSTRACT

An oxide semiconductor layer in a thin-film transistor includes In, Ga, Zn and Sn. The respective ratios of the metal elements to a total (In+Ga+Zn+Sn) of all the metal elements in the oxide semiconductor layer are: In: 20 to 45 atom %, Ga: 5 to 20 atom %, Zn: 30 to 60 atom %, and Sn: 9 to 25 atom %.

### BACKGROUND ART

The present invention relates to a thin film transistor containing an oxide semiconductor layer. The thin film transistor according to the present invention is suitably used in a display device such as a liquid crystal display or an organic EL display.

### BACKGROUND ART

Amorphous oxide semiconductors have high carrier mobility as compared with amorphous silicon. Amorphous oxide semiconductors have large optical band gap and can be deposited at low temperature. Amorphous oxide semiconductors are expected to be applied to a next generation display requiring large size, high resolution and high driving, a resin substrate having low heat resistance, and the like.

Of various oxide semiconductors, In—Ga—Zn—O (IGZO) amorphous oxide semiconductor comprising indium, gallium, zinc and oxygen is widely known as disclosed in Patent Documents 1 to 3.

However, field effect mobility when a thin film transistor (TFT) has been prepared using the IGZO amorphous oxide semiconductor is 10 cm²/Vs or less. On the other hand, a material having higher mobility is required.

Patent Document 4 discloses a thin film transistor of oxide semiconductor (IGZO+Sn) containing In, Ga, Zn and Sn. However, regarding mobility, the patent document merely describes a large-sized element having a channel length of about 1000 μm. The patent document describes that the mobility of the element exceeds 20 cm²/Vs, but the mobility does not reach 20 cm²/Vs in the element having a channel length of about to 20 μm. Furthermore, the patent document does not contain the description relating to stress stability and drain current to TFT size.

Patent Document 5 and Patent Document 6 disclose a thin film transistor of IGZO+Sn, but its mobility does not reach 20 cm²/Vs. Furthermore, Patent Document 7 contains the description relating to a thin film transistor having the mobility exceeding 20 cm²/Vs, but specific technology in IGZO+Sn is not made therein. Additionally, the patent document does not contain the description relating to the compatibility of on-current dependency to a channel size, high mobility and photo-induced stress stability.

### PRIOR ART DOCUMENT

### Patent Document

Patent Document 1: JP-A-2010-219538

Patent Document 2: JP-A-2011-174134

Patent Document 3: JP-A-2013-249537

Patent Document 4: JP-A-2010-118407

Patent Document 5: JP-A-2011-108873

Patent Document 6: JP-A-2012-114367

Patent Document 7: JP-A-2014-229666

### SUMMARY OF THE INVENTION

### Problems that the Invention is to Solve

The present invention has been made in view of the above circumstances, and an object of the present invention is to provide a thin film transistor having high mobility of 20 cm²/Vs or more. Another object of the present invention is to provide a thin film transistor containing an oxide semiconductor layer having photo-induced stress stability, in which drain current value has a proportional relationship with a channel size (channel width W/channel length L) of the thin film transistor, in addition to the thin film transistor having high mobility.

### Means for Solving the Problems

As a result of extensive investigations, the present inventors have found that the above problems can be solved by adopting a specific composition in an oxide semiconductor layer in a thin film transistor.

Specifically, the present invention is as follows.

[1] A thin film transistor including at least a gate electrode, a gate insulating film, an oxide semiconductor layer, a source-drain electrode and at least one layer of a passivation film on a substrate, wherein metal elements constituting the oxide semiconductor layer contain In, Ga, Zn and Sn, and respective ratios of the metal elements to a total (In+Ga+Zn+Sn) of the all metal elements in the oxide semiconductor layer satisfies:

In: 20 to 45 atom %,

Ga: 5 to 20 atom %,

Zn: 30 to 60 atom %, and

Sn: 9 to 25 atom %.

[2] The thin film transistor described in [1] above, wherein in the oxide semiconductor layer, a proportion (Zn/Sn) of Zn to Sn occupied in all metal elements is more than 2.4 times, and a proportion (In/Ga) of In to Ga is more than 2.0 times.
[3] The thin film transistor described in [1] or [2] above, wherein a ratio (Rsh′/Rsh) between sheet resistance Rsh of the oxide semiconductor layer just after forming the passivation film and sheet resistance Rsh′ of the oxide semiconductor layer thereafter conducting a post-annealing treatment is more than 1.0.
[4] The thin film transistor described in any one of [1] to [3] above, wherein sheet resistance before forming the passivation film is 1.0×10⁵ Ω/square or less.
[5] The thin film transistor described in any one of [1] to [4] above, wherein a ratio (D′/D) between carrier density D of the oxide semiconductor layer just after forming the passivation film and carrier density D′ of the oxide semiconductor layer after conducting a post-annealing treatment is 1.5 or less (desirably 1.0 or less).
[6] The thin film transistor described in any one of [1] to [5] above, wherein the oxide semiconductor is a semiconductor film having oxygen bonded to at least a part of metal atoms.
[7] The thin film transistor described in any one of [1] to [6] above, wherein an OH group of a silicon oxide film as the passivation film increase by diffusing in a surface of an oxide semiconductor.
[8] The thin film transistor described in any one of [1] to [7] above, wherein the oxide semiconductor layer has an amorphous structure or at least partially crystallized amorphous structure.
[9] The thin film transistor described in any one of [1] to [8] above, which is an etch stop type further including an etch stopper layer just above the oxide semiconductor layer.
[10] The thin film transistor described in any one of [1] to [8] above, which is a back channel etch type that does not include an etch stopper layer just above the oxide semiconductor layer.

### Effect of the Invention

According to the present invention, a thin film transistor having high mobility of 20 cm²/Vs or more, having its drain current controlled to the proportional relationship with a channel size (channel width W/channel length L) of TFT, and having photo-induced stress stability can be provided.

### BRIEF DESCRIPTION OF THE DRAWINGS

FIG. 1(A) is a schematic top view of the thin film transistor according to the present invention, and FIG. 1(B) is a schematic cross-sectional view of the thin film transistor of the present invention.

FIG. 2(A) and FIG. 2(B) are graphs showing the dependency of drain current (Vg=30V) to a channel size (channel width W/channel length L) of the thin film transistor. FIG. 2(A) is the case of Rsh′/Rsh≤1.0 and FIG. 2(B) is the case of Rsh′/Rsh=10.71.

FIG. 3 is a graph showing the relationship between transition of sheet resistance of an oxide semiconductor and the composition of an oxide semiconductor in each step during manufacturing a thin film transistor.

FIG. 4 is OH profile in a depth direction of the thin film transistor in the examples.

FIG. 5 is O profile in a depth direction of the thin film transistor in the examples.

### MODE FOR CARRYING OUT THE INVENTION

The thin film transistor according to the present invention includes at least a gate electrode, a gate insulating film, an oxide semiconductor layer, a source-drain electrode and at least one layer of a passivation film on a substrate, wherein metal elements constituting the oxide semiconductor layer is In—Ga—Zn—Sn oxide containing In, Ga, Zn and Sn.

By appropriately controlling the proportion (atomic ratio) of each metal element to the total (In+Ga+Zn+Sn) of all metal elements in the oxide semiconductor layer, for example, in the case of a thin film transistor having high mobility, when carrier density has been measured in a film thickness of an oxide semiconductor thin film of 300 nm, the carrier density is 1×10¹⁷ cm³/Vs or more before post-annealing and the carrier density after post-annealing at 300° C. does not sometimes increase. In such a case, transistor size dependency of drain current is secured while securing high mobility.

Furthermore, in the case where an OH group of the oxide semiconductor thin film increase by the post-annealing, the improvement of photo-induced stress stability is achieved while securing high mobility. By the increase of the OH group of the oxide semiconductor thin film, oxygen-related defect and unstable hydrogen-related defect of a channel layer are effectively suppressed and stable metal-oxygen bond can be formed. Particularly, as shown from the results of SIMS analysis described hereinafter, the effect is accelerated at the back channel side. Therefore, both high mobility and stress stability such as photo-induced stress stability can be satisfied while suppressing the increase of a carrier concentration of a thin film.

The respective ratios of the metal elements to the total (In+Ga+Zn+Sn) of all the metal elements in the oxide semiconductor layer is as follows.

In: 20 to 45 atom %,

Ga: 5 to 20 atom %,

Zn: 30 to 60 atom %, and

Sn: 9 to 25 atom %.

Above all, In is preferably 25 atom % or more and preferably 35 atom % or less. Ga is preferably 10 atom % or more and preferably 15 atom % or less. When Ga amount is 5 atom % or less, stress stability is deteriorated. Therefore, Ga is 5 atom % or more. Zn is preferably 40 atom % or more and preferably 50 atom % or less. Sn is preferably 11 atom % or more and 18 atom % or less.

The proportion of Zn to Sn occupied in the all metal elements is preferably more than 2.4 times, and the proportion of In to Ga is preferably more than 2.0 times.

(In/Ga) exceeding 2.0 indicates that a certain amount of In is required to Ga amount in order that the thin film transistor has high mobility. Furthermore, (Zn/Sn) exceeding 2.4 indicates that a certain amount of Zn is required to Sn amount in order to secure a channel size (channel width W/channel length L) dependency of drain current. When Zn proportion to Sn is low, the state of high conductivity is easy to be formed, e.g., crystalline Sn oxide is easily formed, and the change of current path or the fluctuation of effective channel size as described above is accelerated. For this reason, (Zn/Sn) is more than 2.4.

(Zn/Sn) value is more preferably 3.0 or more and preferably 5.0 or less.

(In/Ga) value is more preferably 2.0 or more and preferably 5.0 or less.

The oxide semiconductor layer preferably has an amorphous structure or at least partially crystallized amorphous structure. Specifically, the oxide forming the oxide semiconductor layer is preferably amorphous or at least partially crystallized amorphous. The structure of the oxide can be obtained by controlling a gas pressure to a range of 1 to 5 mTorr, and after forming the passivation film, heat-treating at a temperature of 200° C. or higher, in forming the oxide semiconductor layer.

Sheet resistance of the oxide semiconductor layer before forming the passivation film, that is, after depositing the oxide semiconductor layer by sputtering and then conducting a heat treatment, is preferably 1.0×10⁵ Ω/square or less and more preferably 5.0×10⁴ Ω/square or less. The oxide semiconductor thin film having such sheet resistance is preferred to increase mobility of a thin film transistor.

The sheet resistance of the general IGZO oxide semiconductor layer shows the value exceeding 1.0×10⁵ Ω/square in many cases. This is particularly remarkable in the case of the thin film transistor having the oxide semiconductor layer having such sheet resistance. The sheet resistance of the oxide semiconductor thin film after forming the passivation film tends to increase in its manufacturing step. The reason for this is that the oxide semiconductor generally has band gap but band bending occurs by the formation of the passivation film.

The sheet resistance Rsh of the oxide semiconductor layer just after forming the oxide semiconductor layer and then further forming the passivation film is preferably lower than the sheet resistance Rsh′ of the oxide semiconductor layer after conducting the post-annealing treatment after the formation of the passivation film. Specifically, the (Rsh′/Rsh) value is preferably more than 1.0 and more preferably 3.0 or more. Comparing the sheet resistance of the oxide semiconductor layer when the heat treatment has been conducted under two conditions at different temperatures in the post-annealing after the formation of the passivation film, the fluctuation is preferably large. For example, in the comparison of the respective sheet resistances of the oxide semiconductor layers at the post-annealing temperature of 290° C. and the post-annealing temperature of 250° C., (sheet resistance of oxide semiconductor layer after post-annealing at 290° C.)/(sheet resistance of oxide semiconductor layer after post-annealing at 250° C.) is preferably less than 0.6 or more than 1.6.

Increasing the sheet resistance of the oxide semiconductor layer (Rsh′/Rsh>1.0) by the post-annealing treatment corresponds to the case where resistance value difference at two level post-annealing temperatures is large. In the case of Rsh′/Rsh≤1.0, that is, 0.6≥sheet resistance of oxide semiconductor layer after post-annealing at 290° C.)/(sheet resistance of oxide semiconductor layer after post-annealing at 250° C.) this indicates that a region having low resistance value capable of becoming current path at a part of the channel, not overall channel, and the presence of such a region indicates that current path of a transistor changes or the effective channel size of a transistor has changed. When the region is formed, linearity of drain current Id (in this case, drain current of Vg=30V) is not secured to W/L of the transistor as shown in FIG. 2(A), that is, the drain current is not controlled in the relation of direct proportion to a channel size (channel width W/channel length L) of TFT. This means that many hydrogens are injected from SiNx layer containing many hydrogens constituting the protective layer by the post-annealing, act as donors and affect electrically such as increasing carrier. The case satisfying the above (for example, the case as in FIG. 2(B)) does not affect (is difficult to affect) electrically and as a result, the drain current Id secures linearity to W/L of a transistor.

On the other hand, for example, the linearity of dependency to drain current Id (Vg=30V) and channel size (channel width W/channel length L) of a thin film transistor in the case of Rsh′/Rsh=10.71 as in the thin film transistor of No. 5 in the examples described hereinafter is secured.

From the above, when the metal element composition constituting the oxide semiconductor layer is within the above range and the sheet resistance of the oxide semiconductor layer satisfies the above relationship, the drain current and channel size (channel width W/channel length L) secure linearity and additionally saturated mobility of TFT satisfies 20 cm²/Vs or more, which are preferred. The thin film transistor according to the present invention shows very low value of about 1V in photo-induced stress stability evaluation described hereinafter.

As described above, by the increase of the OH group of the oxide semiconductor thin film, oxygen-related defect and unstable hydrogen-related defect of the channel layer are effectively suppressed, stable metal-oxygen bond can be formed and the OH group of the oxide semiconductor thin film is increased. In such a case, photo-induced stress stability is improved while securing high mobility. Therefore, a ratio (D′/D) between carrier density D of the oxide semiconductor layer just after the formation of the passivation film and carrier density D′ of the oxide semiconductor after the post-annealing treatment, that depends on the presence or absence of oxygen-related defect and the like before post-annealing is preferably 1.5 or less and more preferably 1.0 or less. As one example, the carrier concentration of the oxide semiconductor thin film is preferably less than 1×10¹⁹/cm³ after post-annealing and is preferably 5×10¹⁶/cm³ or more in exhibiting high mobility.

The thin film transistor of the present invention may be any form of an etch stop type having an etch stopper layer and a back channel etch type that does not have an etch stopper layer, just above the oxide semiconductor layer. However, the damage of back channel of the oxide semiconductor layer is small in the etch stop type having an etch stopper layer. Therefore, the etch stop type is more preferred from the standpoint of controllability of sheet resistance of the semiconductor film.

The passivation film in the present invention is constituted of at least one layer and preferably two or more layers. When the passivation film is constituted of two or more layers, controllability of sheet resistance of the oxide semiconductor layer is improved, and this is preferred. The reason for this is that in the case where the passivation film is a single layer composed of only silicon nitride film (SiNx), the SiNx film has very large hydrogen content, and hydrogens easily diffuse in the semiconductor layer, act as donor and as a result, fluctuate in a direction greatly decreasing sheet resistance. Examples of the passivation film include silicon oxide film (SiOx film), SiNx film, an oxide such as Al₂O₃ or Y₂O₃, and laminate films of those. When the passivation film is constituted of two or more layers, the component of the first layer preferably differs from the component of the second and subsequent layers. Those films can be formed by the conventional method such as CVD (Chemical Vapor Deposition) method. Of those, the passivation film containing SiNx film is preferred from the standpoint easy control of sheet resistance of the oxide semiconductor layer within a certain range.

The passivation film has a thickness of preferably 100 to 500 μm and more preferably 250 to 300 μm. When the passivation film is a laminate film of two or more layers, the total thickness is preferably within the above range. When the passivation film is formed by CVD method, the film thickness can be changed by adjusting deposition time. Thickness of the passivation film can be measured by optical measurement, step measurement or SEM observation.

As the substrate, gate electrode, gate insulating film and source-drain electrode in the present invention, the materials generally used can be used. Examples of the substrate include a transparent substrate, an Si substrate, a thin metal sheet such as stainless steel, and a resin substrate such as PET film. The thickness of the substrate is preferably 0.3 mm to 1.0 mm from the standpoint of workability. As the gate electrode and source-drain electrode, Al alloy, Al alloy having formed thereon a thin film or an alloy film of Mo, Cu, Ti or the like, and the like can be used. The thickness is not particularly limited, but the thickness of the gate electrode is preferably 100 to 500 μm from the standpoint of electric resistance, and the thickness of the source-drain electrode is preferably 100 to 400 μm from the standpoint of electric resistance. As the production method of those electrodes, the conventional methods can be used.

The gate insulating film may be a single layer and may be two or more layers, and the gate insulating film conventionally used can be used. Examples of the gate insulating film include SiOx film, SiNx film, an oxide such as Al₂O₃ or Y₂O₃, and laminate films of those. When the gate insulting film is two or more layers, the film having different component between the first layer and the second and subsequent layers is preferred. The gate insulating film can be formed by the method conventionally used, and the example thereof includes CVD method. The thickness of the gate insulating film is preferably 50 to 300 μm from the standpoint of electrostatic capacity of a thin film transistor. When the gate insulating film is a laminate film of two or more layers, the total film thickness is preferably within the above range.

### <Manufacturing Method of Thin Film Transistor>

The thin film transistor according to the present invention is not limited to an etch stop type and a back channel etch type and can be manufactured by the same method under the same conditions as in conventional methods and conditions. One example of the manufacturing method of TFT is described below, but the present invention is not limited to this. A gate electrode is formed on a substrate by a sputtering method or the like. After patterning, a gate insulating film is deposited by CVD method or the like. The patterning can be conducted by the ordinary method. Heating is conducted in the deposition of the gate insulting film. An oxide semiconductor layer is deposited by a sputtering method or the like and patterning is then conducted. Thereafter, a pre-annealing treatment is conducted and deposition of an etch stopper layer and patterning are conducted as necessary.

Subsequently, a source-drain electrode is formed by a sputtering method or the like, patterning is conducted and a passivation film is then deposited. Heating is conducted in the deposition of the passivation film. In the case of a back channel etch type, after conducting recovery annealing, the deposition of a passivation film is again conducted. Thereafter, etching of a contact hole is conducted and a post-annealing treatment (heat treatment) is then conducted. Thus, TFT can be obtained.

### EXAMPLE

### Example 1

### [Manufacturing of Thin Film Transistor]

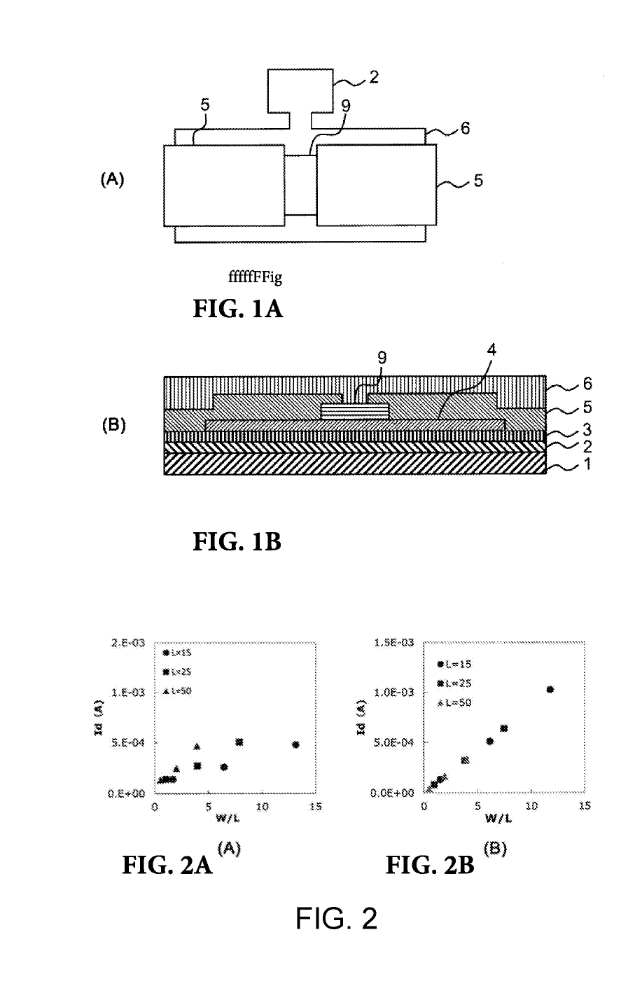

The manufacturing method of a thin film transistor is described below by reference to FIG. 1. Mo film as a gate electrode 2 was deposited in a thickness of 250 nm on a glass substrate 1 (trade name: EAGLE 2000 manufactured by Eagle, diameter: 4 inches, thickness: 0.7 mm) and a silicon oxide (SiOx) film having a thickness of 250 nm was deposited as a gate insulating film 3 on the Mo film under the following conditions.

Carrier gas: Mixed gas of SiH₄ and N₂O

Deposition power: 0.96 W/cm²

Deposition temperature: 320° C.

Gas pressure during deposition: 133 Pa

An oxide semiconductor layer 4 as In—Ga—Zn—Sn—O film shown in Table 1 or Table 2 was deposited in a film thickness of 40 nm under the following conditions. For comparison, each of In—Ga—Zn—O film, In—Ga—Sn—O film and In—Zn—Sn—O film was deposited in a film thickness of 40 nm. The proportion of each metal element in the oxide semiconductor layer is shown in Table 3.

### (Formation of Oxide Semiconductor Layer)

Deposition method: DC sputtering method

Apparatus: CS200 manufactured by ULVAC, Inc.

Deposition temperature: Room temperature

Gas pressure: 1 mTorr

Carrier gas: Ar

Oxygen partial pressure: 100×O₂/(Ar+O₂)=4 vol %

Deposition power; 2.55 W/cm²

Analysis of the content of each metal element of the oxide semiconductor layer 4 was conducted by separately preparing a sample obtained by forming each oxide semiconductor layer having a film thickness of 40 nm on a glass substrate by a sputtering method in the same manner as above. The analysis was conducted by ICP (Inductively Coupled Plasma) emission spectrography using CIROS Mark II manufactured by Rigaku Corporation.

After depositing the oxide semiconductor layer 4 as above, patterning was conducted by photolithography and wet etching. ITO-07N manufactured by Kanto Chemical Co., Inc. was used as a wet etchant. It was confirmed in the present examples that residue by wet etching was not observed in all oxide semiconductor layers tested and etching could be appropriately performed. After patterning the oxide semiconductor layer, pre-annealing was conducted in order to improve film quality. The pre-annealing was conducted at 350° C. for 1 hour in an air atmosphere.

As an etch stopper layer 9 for protecting an oxide semiconductor thin film transistor, silicon oxide film (film thickness: 100 nm) was deposited on the oxide semiconductor layer 4. To form a source-drain electrode 5 (imitation), a pure Mo film having a film thickness of 200 nm was formed and patterned by a photolithography process. Thus, the source-drain electrode 5 was formed.

### (Formation of Source-Drain Electrode)

Deposition conditions of the pure Mo film are shown below.

Power charged: DC 300W (deposition power: 3.8 W/cm²)

Carrier gas: Ar

Gas pressure: 2 mTorr

Substrate temperature: Room temperature

A laminate film having a total film thickness of 250 nm obtained by laminating SiOx film having a film thickness of 100 nm and SiNx film having a film thickness of 150 nm was further formed as a passivation film 6 by a plasma CVD method. Mixed gas of SiH₄, N₂ and N₂O was used in the formation of the SiOx film and a mixed gas of SiH₄, N₂ and NH₃ was used in the formation of the SiNx film. Deposition conditions in those cases were as follows.

### (Formation of Passivation Film)

Deposition power: 0.32 W/cm²

Deposition temperature: 150° C.

Gas pressure during deposition: 133 Pa

A contact hole for probing for evaluation of transistor properties was formed in the passivation film 6 by photolithography and dry etching. Thereafter, heat treatment was conducted at 250° C. for 30 minutes and at 290° C. for 30 minutes, in the nitrogen atmosphere. Thus, the thin film transistors of Nos. 1 to 20 were obtained.

### (TLM Evaluation)

TLM (Transfer Length Method) measurement was conducted on the oxide semiconductor layer to obtain sheet resistance Rsh. In the TLM measurement, as backside processing of Si substrate in TFT, the pattern formation side of the substrate surfaces was covered with a resist, dipping was conducted at room temperature for about 4 minutes using buffered hydrofluoric acid, water cleaning was conducted for 10 minutes, and after confirming water repellency, drying treatment was conducted. Current-voltage properties among a plurality of electrodes were measured changing a distance between electrodes in the oxide semiconductor layer and electrical resistance values between electrodes were obtained. Here, the electrical resistance values between electrodes at 5 spots in total were obtained.

In a graph obtained by plotting the electrical resistance values thus obtained as a vertical axis and a distance (L, μm) between electrodes as a horizontal value, the value of y-intercept corresponds to the value of 2 times (2×Rct) of contact resistance Rct and the value of x-intercept corresponds to the effective contact length (LT: transfer length), respectively. From the above, contact resistivity ρc is represented by the following formula. Z is an electrode width.

ρc=Rct×LT×Z

The sheet resistance Rsh (Ω/square) is a value obtained by multiplying the electrode width Z by an electrical resistance value (SI) between each of electrodes and further dividing by the distance (L) between electrodes.

The results are shown in “TLM measurement” of Table 1. In Table 1, “Rsh (Ω/square) before PV” indicates sheet resistance before the formation of a passivation film, “Rsh after PA at 250° C./Rsh after PV” indicates a ratio obtained by dividing sheet resistance after post-annealing at 250° C. by sheet resistance after the formation of a protective sheet, “Rsh after PA at 290° C./Rsh after PV” indicates a ratio obtained by dividing sheet resistance after post-annealing at 290° C. by sheet resistance after the formation of a protective sheet, and “Rsh after PA at 290° C./Rsh after PA at 250° C.” indicates a ratio obtained by dividing sheet resistance after post-annealing at 290° C. by sheet resistance after post-annealing at 250° C. “Rsh before PV (Ω/square)” is preferably 1.0×10⁵ Ω/square or less. The respective values of “Rsh after PA at 250° C./Rsh after PV” and “Rsh after PA at 290° C./Rsh after PV” are preferably more than 1.0. The “Rsh after PA at 290° C./Rsh after PA at 250° C.” is preferably less than 0.6 or more than 1.6.

(Carrier Density after Pre-Annealing)

Oxide semiconductors having the respective compositions were prepared in oxygen partial pressure 4%, 200 W and 1 mTorr and then subjected to pre-annealing treatment at 350° C. for 1 hour under the atmosphere. Thereafter, an electrode was formed on each oxide semiconductor by mask sputtering, a hall effect element was prepared and carrier mobility was calculated from the measurement of the hall effect.

The carrier density for calculating the carrier mobility can be measured by, for example, the following method.

### <Measurement of Carrier Density>

The carrier density is measured by van de Pauw method using hall measurement apparatus (“Resitest 8310” manufactured by Toyo Technica). The sample used in the hall measurement is obtained by forming a square-shaped oxide semiconductor thin film (film thickness: 200 nm) having 5 mm square size as an element on a glass substrate by sputtering and then forming Mo electrode on four corners of a square pattern of the oxide semiconductor thin film using a sputtering method. Electrode wires are attached to the four electrodes respectively using a conductive paste, and carrier density was calculated from the measurement results of specific resistance and hall coefficient. The measurement was conducted under the conditions of applied magnetic field: 0.5 T and measurement temperature: room temperature.

The carrier density is preferably 5×10¹⁶/cm³ or more in order to exhibit high mobility.

TABLE 1

| | | | | | | Measurement of hall effect | | TLM measurement | | | | |
|---|---|---|---|---|---|---|---|---|---|---|---|---|
| | | | | | | After pre-annealing | | | | | Rsh after PA | |
| | | | | | | Carrier | Carrier | | Rsh after PA | Rsh after PA | at 290° C./ | |
| | Composition | | | | | density | mobility | Rsh before PV | at 250° C./ | at 290° C./ | Rsh after PA | |
| No. | In | Ga | Zn | Sn | — | (/cm³) | (cm²/Vs) | (Ω/square) | Rsh after PV | Rsh after PV | at 250° C. | Acceptance |
| 1 | 33.3 | 33.3 | 33.3 | — | IGZO | 1.40 × 10¹⁵ | 10.5 | 3.2 × 10⁵ | — | — | 0 | X |
| 2 | 17 | 17 | 45 | 21 | IGZTO | 1.40 × 10¹⁵ | 11.5 | 1.4 × 10⁵ | 1.9 | 0.1 | 0.11 | X |
| 3 | 20 | — | 56.6 | 23.4 | IZTO | 8.90 × 10¹⁶ | 16.1 | 4.7 × 10³ | 3.6 | 0.4 | 0.08 | X |
| 4 | 32.3 | 15.9 | 26 | 25.8 | IGZTO | 4.30 × 10¹⁷ | 15.8 | 1.3 × 10⁴ | 0.4 | 0.3 | 0.6 | X |
| 5 | 26.6 | 10.8 | 51.2 | 11.7 | IGZTO | 1.70 × 10¹⁷ | 15.1 | 2.7 × 10⁴ | 35.2 | 10.7 | 0.16 | ◯ |
| 6 | 42.7 | 26.7 | — | 30.6 | IGTO | 3.20 × 10¹⁹ | 6.5 | 3.1 × 10³ | 0.2 | 0.1 | 1.01 | X |
| 7 | 23.6 | 7.45 | 52.1 | 16.8 | IGZTO | 1.10 × 10¹⁷ | 14.9 | 2.1 × 10⁴ | 20.7 | 5.8 | 0.32 | ◯ |
| 8 | 38.3 | 12.2 | 40.2 | 9.31 | IGZTO | 2.80 × 10¹⁷ | 15.3 | 3.5 × 10⁴ | 15.2 | 3.9 | 0.22 | ◯ |
| 9 | 31.5 | 11.8 | 39.8 | 16.8 | IGZTO | 6.80 × 10¹⁷ | 14.8 | 4.0 × 10³ | 0.6 | 0.46 | 0.77 | ◯ |
| 10 | 22.7 | 5.8 | 53 | 18.5 | IGZTO | 9.50 × 10¹⁶ | 14.8 | 1.7 × 10⁴ | 19.5 | 3 | 0.4 | ◯ |
| 14 | 37.7 | 18.3 | 29.2 | 14.8 | IGZTO | 4.04 × 10¹⁶ | 13.5 | 3.3 × 10⁴ | 15.4 | 6.6 | 0.37 | X |
| 15 | 42.9 | 13.2 | 32.2 | 11.7 | IGZTO | 2.65 × 10¹⁷ | 17.3 | 1.1 × 10⁴ | 6.2 | 3.9 | 0.37 | ◯ |

### (Evaluation of Static Properties (Field Effect Mobility (Mobility), Vth and S Value)

Drain current (Id)-gate voltage (Vg) properties were measured using TFT having the oxide semiconductor layer having the composition shown in Table 2. The Id-Vg properties were measured by setting gate voltage and voltage of source-drain electrode and using a prober and a semiconductor parameter analyzer (Keithley 4200SCS).

Gate voltage: −30 to 30V (step 0.25V)

Source voltage: 0V

Drain voltage: 10V

Measurement temperature: Room temperature

Field effect mobility (mobility), shift amount of threshold voltage (Vth) and S value were calculated from the Id-Vg properties measured. The Vth was a value of Vg when drain current flows in an amount of 10⁻⁹ Å. “Id vs W/L” was plotted by Id value of Vg=30V and W/L value including channel width (W) and channel length (L) of TFT.

### (Evaluation of Stress Stability)

Using TFT having oxide semiconductor layers having the respective compositions, stress stability (ΔVth@NBTIS) was evaluated as follows. The stress stability was evaluated by conducting a stress application test irradiating light while applying negative bias to a gate electrode. Stress application conditions are as follows.

Gate voltage: −20V

Source/drain voltage: 10V

Substrate temperature: 60° C.

Photo-induced stress conditions

Stress application time: 2 hours

Light intensity: 25000 NIT

Light source: White LED

The ΔVth used herein is (Vth@2 hours later of stress application)-(Vth@ immediately after stress application).

The above results are shown in Table 2. Furthermore, Table 3 referred above is also shown below.

TABLE 2

| | | | | | | TFT | | | | |
|---|---|---|---|---|---|---|---|---|---|---|
| | | | | | | Post-annealing at 250° C. | | | | |
| | | | | | | | | | | ΔVth@ |
| | Composition | | | | | Mobility | Vth | S | | NBTIS |
| No. | In | Ga | Zn | Sn | — | (cm²/Vs) | (V) | (V/dec) | Id vs W/L | (V) |
| 1 | 33.3 | 33.3 | 33.3 | — | IGZO | 9.8 | 2.75 | 0.3 | Linearity (◯) | 3.5 |
| 2 | 17 | 17 | 45 | 21 | IGZTO | 11.5 | 2 | 0.275 | Linearity (◯) | 3 |
| 3 | 20 | — | 56.6 | 23.4 | IZTO | 20.3 | 1.8 | 0.22 | Linearity (◯) | 6.8 |
| 4 | 32.3 | 15.9 | 30 | 21.8 | IGZTO | 14.9 | 2 | 0.25 | Linearity (◯) | 3 |
| 5 | 26.6 | 10.8 | 51.2 | 11.7 | IGZTO | 15.9 | 1.5 | 0.25 | Linearity (◯) | 4 |
| 6 | 42.7 | 26.7 | — | 30.6 | IGTO | 17.3 | 0.75 | 0.2 | Linearity (◯) | 5.5 |
| 7 | 23.6 | 7.45 | 52.1 | 16.8 | IGZTO | 13.7 | 1 | 0.22 | Linearity (◯) | 4.5 |
| 8 | 38.3 | 12.2 | 40.2 | 9.31 | IGZTO | 14.4 | 1.2 | 0.24 | Linearity (◯) | 3.2 |
| 9 | 31.5 | 11.8 | 39.8 | 16.8 | IGZTO | 16.6 | 1 | 0.23 | Linearity (◯) | 3 |
| 10 | 22.7 | 5.8 | 53 | 18.5 | IGZTO | 15.9 | 1.5 | 0.22 | Linearity (◯) | 3.5 |
| 11 | 21 | 5.1 | 58 | 15.9 | IGZTO | 15.5 | 1.4 | 0.24 | Linearity (◯) | 3.8 |
| 12 | 11.3 | 11.1 | 52.1 | 25.5 | IGZTO | 12.4 | 2 | 0.29 | Linearity (◯) | 4 |
| 13 | 31.5 | 11.8 | 42.8 | 13.9 | IGZTO | 17.2 | 2.2 | 0.26 | Linearity (◯) | 3 |
| 14 | 37.7 | 18.3 | 29.2 | 14.8 | IGZTO | 13.7 | 2.75 | 0.27 | Linearity (◯) | 4.8 |
| 15 | 42.9 | 13.2 | 32.2 | 11.7 | IGZTO | 17.8 | 1.25 | 0.24 | Linearity (◯) | 5.5 |
| 16 | 55.2 | 11.1 | 25.6 | 8.1 | IGZTO | 19.1 | −2.25 | 0.3 | Linearity (◯) | 6.2 |
| 17 | 34.2 | 24.1 | 30.1 | 11.6 | IGZTO | 10.8 | 1.75 | 0.22 | Linearity (◯) | 3.3 |
| 18 | 13 | 12.2 | 69.1 | 5.7 | IGZTO | 10.9 | 2.5 | 0.41 | Linearity (◯) | 7.5 |
| 19 | 24 | 7.5 | 33.3 | 35.2 | IGZTO | 10.7 | 2.25 | 0.3 | Linearity (◯) | 5.5 |
| 20 | 28.1 | 27.8 | 40 | 4.1 | IGZTO | 10.2 | 2.5 | 0.31 | Linearity (◯) | 3.3 |

| | TFT | | | | | |
|---|---|---|---|---|---|---|
| | Post-annealing at 290° C. | | | | | |
| | | | | | ΔVth@ | |
| | Mobility | Vth | S | | NBTIS | |
| No. | (cm²/Vs) | (V) | (V/dec) | Id vs W/L | (V) | Acceptance |
| 1 | 9.7 | 2 | 0.25 | Linearity (◯) | 3.25 | X |
| 2 | 13.5 | 1.5 | 0.24 | Linearity (◯) | 2.75 | X |
| 3 | 23 | 0 | 0.18 | non-Linearity (X) | 6.75 | X |
| 4 | 25.7 | 0.8 | 0.21 | non-Linearity (X) | 1 | X |
| 5 | 30.7 | 0 | 0.24 | Linearity (◯) | 0.75 | ◯ |
| 6 | 20.4 | 0.5 | 0.19 | non-Linearity (X) | 5.75 | X |
| 7 | 20 | 0.75 | 0.23 | Linearity (◯) | 3.75 | ◯ |
| 8 | 26.4 | 0.75 | 0.27 | Linearity (◯) | 1 | ◯ |
| 9 | 26.6 | 0.75 | 0.23 | Linearity (◯) | 1.5 | ◯ |
| 10 | 22.7 | 1 | 0.21 | Linearity (◯) | 4.75 | ◯ |
| 11 | 22.2 | 1 | 0.24 | Linearity (◯) | 4.75 | ◯ |
| 12 | 13.9 | 2.1 | 0.25 | non-Linearity (X) | 4.2 | X |
| 13 | 27.1 | 2.5 | 0.25 | Linearity (◯) | 2 | ◯ |
| 14 | 18.5 | 1 | 0.33 | Linearity (◯) | 1 | X |
| 15 | 26.8 | 0.5 | 0.23 | Linearity (◯) | 1.75 | ◯ |
| 16 | 18.9 | −5.2 | 0.35 | Linearity (◯) | 8.25 | X |
| 17 | 11.2 | 1.5 | 0.25 | Linearity (◯) | 3 | X |
| 18 | 11 | 3 | 0.42 | Linearity (◯) | 7 | X |
| 19 | 10.6 | 3.25 | 0.28 | non-Linearity (X) | 5.25 | X |
| 20 | 10.5 | 2.8 | 0.29 | Linearity (◯) | 3 | X |

TABLE 3

| No. | In/Ga | In/Sn | Zn/Sn | Ga/Sn |
|---|---|---|---|---|
| 1 | 1 | — | — | — |
| 2 | 1 | 0.8 | 2.1 | 0.8 |
| 3 | — | 0.9 | 2.4 | — |
| 4 | 2 | 1.5 | 1.4 | 0.7 |
| 5 | 2.5 | 2.3 | 4.4 | 0.9 |
| 6 | 1.6 | 1.4 | — | 0.9 |
| 7 | 3.2 | 1.4 | 3.1 | 0.4 |
| 8 | 3.1 | 4.1 | 4.3 | 1.3 |
| 9 | 2.7 | 1.9 | 2.4 | 0.7 |
| 10 | 3.9 | 1.2 | 2.9 | 0.3 |
| 14 | 2.1 | 2.5 | 2 | 1.2 |
| 15 | 3.3 | 3.7 | 2.8 | 1.1 |

As is apparent from Table 2, in the thin film transistor satisfying the requirements of the present invention, particularly by post-annealing the protective layer at 290° C., the carrier mobility is increased to exceed 20 cm²/Vs, Vth shows low value as about 1V and Id vs W/L shows linearity. The stress stability (ΔVth@NBTIS) is low as about 1V and stress stability is excellent.

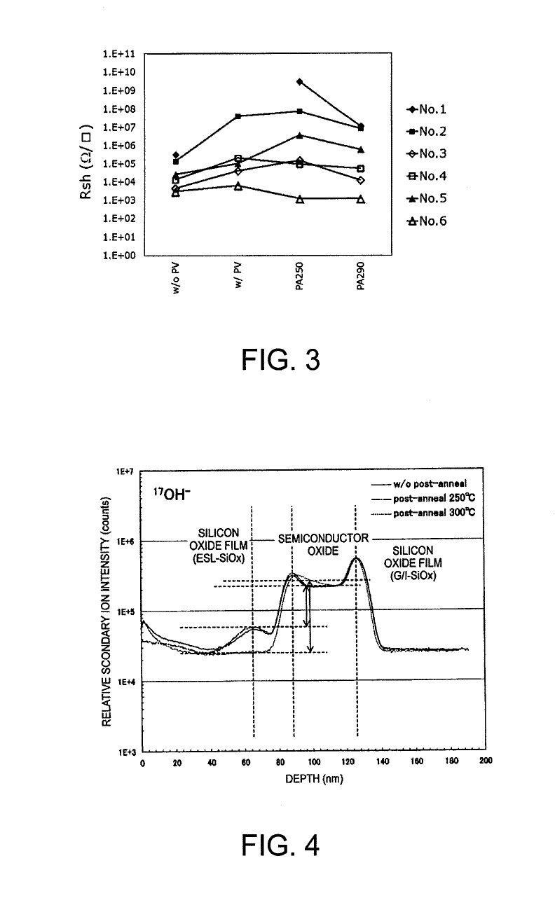

Transition of sheet resistance Rsh in every manufacturing step of the oxide semiconductor layers of the thin film transistors of Nos. 1 to 6 is shown in FIG. 3. In FIG. 3, “w/o PV” means before forming a passivation film, “w/PV” means after forming a passivation film, “PA250” means after forming a passivation film and further subjecting the film to a heat treatment at 250° C., and “PA290” means after the “PA250” further subjecting the film to a heat treatment at 290° C.

### Example 2: Manufacturing of Element for Measurement of Hall Effect

A thin film transistor was manufactured in the same manner as in Example 1, except that the thickness of the oxide semiconductor layer was changed from 40 nm to 300 nm. The results are shown in Table 4.

TABLE 4

| | Measurement of hall effect | | | | |
|---|---|---|---|---|---|
| | After PV | | After PA at 300° C. | | |
| | Carrier | Carrier | Carrier | Carrier | |
| | density | mobility | density | mobility | Judge- |
| No. | (/cm³) | (cm²/Vs) | (/cm³) | (cm²/Vs) | ment |
| 1 | (Impossible | (Impossible | (Impossible | (Impossible | |
| | to determine) | to determine) | to determine) | to determine) | |
| 2 | (Impossible | (Impossible | (Impossible | (Impossible | |
| | to determine) | to determine) | to determine) | to determine) | |
| 3 | 1.50 × 10¹⁷ | 22.7 | 2.10 × 10¹⁷ | 24.1 | Δ |
| 4 | 2.30 × 10¹⁷ | 21.9 | 1.10 × 10¹⁸ | 24.5 | X |
| 5 | 3.31 × 10¹⁷ | 21.9 | 1.17 × 10¹⁷ | 20 | ◯ |
| 6 | 1.55 × 10¹⁸ | 21 | 2.22 × 10¹⁹ | 29 | X |
| 7 | 1.22 × 10¹⁷ | 20.4 | 1.01 × 10¹⁷ | 20.2 | ◯ |
| 8 | 7.40 × 10¹⁷ | 23.2 | 2.60 × 10¹⁷ | 20.5 | ◯ |
| 9 | 8.60 × 10¹⁷ | 22.6 | 5.20 × 10¹⁸ | 24.1 | X |
| 10 | 3.00 × 10¹⁷ | 21.7 | 2.70 × 10¹⁷ | 21.1 | ◯ |
| 14 | 2.40 × 10¹⁷ | 21.5 | 3.60 × 10¹⁷ | 21.7 | Δ |
| 15 | 5.20 × 10¹⁷ | 23.9 | 4.70 × 10¹⁷ | 23.8 | ◯ |

In the present examples, the hall measurement was conducted as the oxide semiconductor thin film being 300 nm in order to avoid the influence of the increase of resistance by band bending or the like of the oxide semiconductor. In No. 1 and No. 2, the hall measurement was difficult both before and after post-annealing. The measurement was possible in No. 3 and the subsequent Nos. In those, the post-annealing was conducted at 300° C. in Nos. 4, 6 and 9, the carrier concentration greatly increases after post-annealing (D′/D≥5), hydrogens contained in large amount in the passivation film SiNx diffuse in the oxide semiconductor layer from SiNx layer and act as carries, and the carrier concentration was increased.

On the other hand, in No. 3 and No. 14, the carrier concentration was increased by the post-annealing, but the increase was slight (D′/D=about 1.5). The presence or absence of (Id) vs (W/L) is shown in Table 1. When the carrier concentration increases by the post-annealing, the dependency of (Id) vs (W/L) tends to be not observed. It is considered that when the carrier concentration increases by the post-annealing, the effective fluctuation of a channel size is increased. The deviation from the channel size shown by the patterning occurs, and thus (Id) vs (W/L) do not have the proportional relationship.

### Example 3

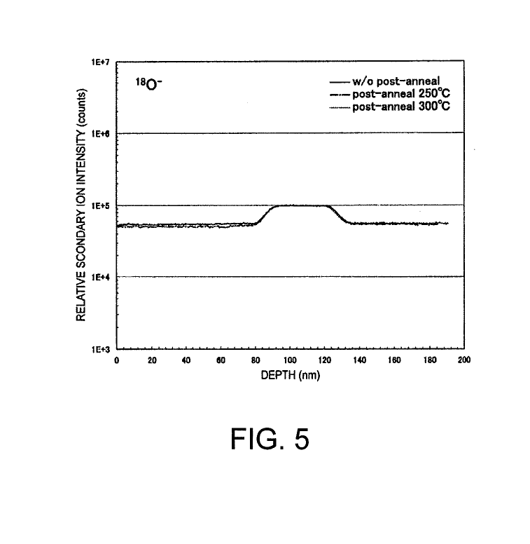

The distribution in a depth direction of OH and O in the sample of No. 5 was shown in FIG. 4 and FIG. 5. In no post-anneal, the OH group in the interface region between ESL (SiOx) of post-anneal 250° C. and the oxide semiconductor, and the OH group in the interface region between ESL (SiOx) of post-anneal 300° C. and the oxide semiconductor, apparent difference was observed in secondary ion intensity of SIMS. After post-anneal 300° C., peak of the OH group in a silicon oxide film in the vicinity of the interface decreases, whereas the OH group in the oxide semiconductor film in the vicinity of the interface increases. Checking ΔVth to LNBTS in Table 1, it says that OH groups in the vicinity of the interface diffuse in oxide semiconductor from the silicon oxide film and OH groups are adsorbed on back channel of the oxide conductor, thereby contributing to the reduction of ΔVth to photo-induced stress. The same effect could be confirmed in the sample of No. 2. On the other hand, in No. 3 and No. 18, diffusion of the OH group (adsorption of OH=repair effect of interfacial defect) is not observed and as a result, it was seen that the reduction of shift of ΔVth by photo-induced stress was not observed.

In the comparison between OH and O, O atoms do not increase. Therefore, O atoms increase as OH groups. It can say that this contributes to the reduction of ΔVth to photo-induced stress as described above.

Although the present invention has been described in detail and by reference to the specific embodiments, it is apparent to one skilled in the art that various modifications or changes can be made without departing the spirit and scope of the present invention. This application is based on Japanese Patent Application No. 2016-35806 filed on Feb. 26, 2016 and Japanese Patent Application No. 2016-182146 filed on Sep. 16, 2016, the disclosures of which are incorporated herein by reference.

### DESCRIPTION OF REFERENCE NUMERALS AND SIGNS

1 Substrate
2 Gate electrode
3 Gate insulating film
4 Oxide semiconductor layer
5 Source-drain electrodes
6 Passivation film
9 Etch stopper layer

1: A thin film transistor, comprising
a gate electrode,
a gate insulating film,
an oxide semiconductor layer,
a source-drain electrode, and
one or more layers of passivation film on a substrate,
wherein the oxide semiconductor layer comprises In, Ga, Zn and Sn, and respective ratios of the metal elements to a total (In+Ga+Zn+Sn) of all the metal elements in the oxide semiconductor layer satisfy:
In: 20 to 45 atom %,
Ga: 5 to 20 atom %,
Zn: 30 to 60 atom %, and
Sn: 9 to 25 atom %.

2: The thin film transistor according to claim 1, wherein in the oxide semiconductor layer, a proportion (Zn/Sn) of Zn to Sn is more than 2.4 times, and a proportion (In/Ga) of In to Ga is more than 2.0 times.

3: The thin film transistor according to claim 1, wherein
a ratio (Rsh′/Rsh) between sheet resistance Rsh of the oxide semiconductor layer just after forming the passivation film and sheet resistance Rsh′ of the oxide semiconductor layer after conducting a post-annealing treatment is more than 1.0, and
the post-annealing treatment is performed after forming the passivation film.

4: The thin film transistor according to claim 1, wherein sheet resistance before forming the passivation film is 1.0×10⁵ Ω/square or less.

5: The thin film transistor according to claim 1, wherein a ratio (D′/D) between carrier density D of the oxide semiconductor layer just after forming the passivation film and carrier density D′ of the oxide semiconductor layer after conducting a post-annealing treatment is 1.5 or less.

6: The thin film transistor according to claim 1, wherein the oxide semiconductor is a semiconductor film having an oxygen element bonded to at least a part of metal atoms.

7: The thin film transistor according to claim 1, wherein OH groups diffuse from the passivation film composed of a silicon oxide and a concentration of OH groups increases at a surface of the oxide semiconductor layer.

8: The thin film transistor according to claim 1, wherein the oxide semiconductor layer has an amorphous structure or a partially crystallized amorphous structure.

9: The thin film transistor according to claim 1, which is an etch stop type further comprising an etch stopper layer just above the oxide semiconductor layer.

10: The thin film transistor according to claim 1, which is a back channel etch type that does not comprise an etch stopper layer just above the oxide semiconductor layer.
